(19) United States
(12) Patent Application Publication
(10) Pub. No.: US 2013/0081688 A1
(43) Pub. Date: Apr. 4, 2013

(54) BACK CONTACTS FOR THIN FILM SOLAR CELLS

(71) Applicants: Haifan Liang, Fremont, CA (US); Hien Minh Huu Le, San Jose, CA (US); Jeroen Van Duren, Palo Alto, CA (US)

(72) Inventors: Haifan Liang, Fremont, CA (US); Hien Minh Huu Le, San Jose, CA (US); Jeroen Van Duren, Palo Alto, CA (US)

(73) Assignee: INTERMOLECULAR, INC., San Jose, CA (US)

(21) Appl. No.: 13/251,509

(22) Filed: Oct. 3, 2011

(51) Int. Cl. H01L 31/02

(52) U.S. Cl. 136/256

(57) ABSTRACT

Method for forming back contact stacks for CIGS and CZTS TFPV solar cells are described wherein some embodiments include adhesion promoter layers, bulk current transport layers, stress management/diffusion barrier layers, optical reflector layers, and ohmic contact layers. Other back contact stacks include adhesion promoter layers, bulk current transport layers, diffusion barrier layers, and ohmic contact layers.

### FIELD OF THE INVENTION

The present invention relates generally to methods for developing back contacts for thin film solar cells. More specifically, methods of developing back contacts for copper indium gallium (sulfide) selenide (CIGS) solar cells, cadmium telluride (CdTe) solar cells, and copper zinc tin (sulfide) selenide (CZTS) solar cells.

### BACKGROUND OF THE INVENTION

Solar cells have been developed as clean, renewable energy sources to meet growing demand. Currently, crystalline silicon solar cells (both single crystal and polycrystalline) are the dominant technologies in the market. Crystalline silicon solar cells must use a thick substrate (>100 um) of silicon to absorb the sunlight since it has an indirect band gap. Also, the absorption coefficient is low for crystalline silicon because of the indirect band gap. The use of a thick substrate also means that the crystalline silicon solar cells must use high quality material to provide long carrier lifetimes to allow the carriers to diffuse to the contacts. Therefore, crystalline silicon solar cell technologies lead to increased costs. Thin film solar cells based on amorphous silicon (a-Si), CIGS, CdTe, CZTS, etc. provide an opportunity to increase the material utilization since only thin films (<10 um) are generally required. CdTe and CZTS films have band gaps of about 1.5 eV and therefore, are efficient absorbers for wavelengths shorter than about 800 nm. The absorption coefficient for CdTe is about 10⁵/cm and the absorption coefficient for CZTS is about 10⁴/cm. CIGS films have bandgaps in the range of 1.0 eV (CIS) to 1.65 eV (CGS) and are also efficient absorbers across the entire visible spectrum. The absorption coefficient for CIGS is about 10⁵/cm. Furthermore, thin film solar cells may be fabricated on inexpensive substrates such as glass, plastics, and thin sheets of metal. Among the thin film solar cells, CIGS has demonstrated the best lab cell efficiency (over 20%) and the best large area module efficiency (>12%).

The increasing demand for environmentally friendly, sustainable and renewable energy sources is driving the development of large area, thin film photovoltaic (TFPV) devices. With a long-term goal of providing a significant percentage of global energy demand, there is a concomitant need for Earth-abundant, high conversion efficiency materials for use in photovoltaic devices. A number of Earth abundant direct-bandgap semiconductor materials now seem to show evidence of the potential for both high efficiency and low cost in Very Large Scale (VLS) production (e.g. greater than 100 gigawatt (GW)), yet relatively little attention has been devoted to their development and characterization.

Among the TFPV technologies, CIGS and CdTe are the two that have reached volume production with greater than 10% stabilized module efficiencies. Solar cell production volume must increase tremendously in the coming decades to meet sharply growing energy needs. However, the supply of In, Ga and Te may impact annual production of CIGS and CdTe solar panels. Moreover, price increases and supply constraints in In and Ga could result from the aggregate demand for these materials used in flat panel displays (FPD) and light-emitting diodes (LED) along with CIGS TFPV. Also, there are concerns about the toxicity of Cd throughout the lifecycle of the CdTe TFPV solar modules. Efforts to develop devices that leverage manufacturing and R&D infrastructure related to TFPV using more widely available and more environmentally friendly raw materials should be considered a top priority for research.

The immaturity of TFPV devices exploiting Earth abundant materials represents a daunting challenge in terms of the time-to-commercialization. That same immaturity also suggests an enticing opportunity for breakthrough discoveries. A quaternary system such as CIGS or CZTS requires management of multiple kinetic pathways, thermodynamic phase equilibrium considerations, defect chemistries, and interfacial control. The vast phase-space to be managed includes deposition, and conversion methods, process parameters, source material choices, compositions, and overall integration schemes. Traditional R&D methods are ill-equipped to address such complexity, and the traditionally slow pace of R&D could limit any new material from reaching industrial relevance when having to compete with the incrementally improving performance of already established TFPV fabrication lines.

However, due to the complexity of the material, cell structure and manufacturing process, both the fundamental scientific understanding and large scale manufacturability are yet to be improved for CIGS and CZTS solar cells. As the photovoltaic industry pushes to achieve grid parity, much faster and broader investigation is needed to explore the material, device, and process windows for higher efficiency and a lower cost of manufacturing process. Efficient methods for forming different types of CIGS and CZTS solar cells that can be evaluated are necessary.

The efficiency of TFPV solar cells depends on many properties of the absorber layer and the buffer layer such as crystallinity, grain size, composition uniformity, density, defect concentration, doping level, surface roughness, etc.

The manufacture of TFPV modules entails the integration and sequencing of many unit processing steps. As an example, TFPV manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

HPC processing techniques have been adapted to the development and investigation of absorber layers and buffer layers for TFPV solar cells as described in U.S. application Ser. No. 13/236,430 filed on Sep. 19, 2011, entitled “COMBINATORIAL METHODS FOR DEVELOPING SUPERSTRATE THIN FILM DEVICES” and having internal docket number (IM0315_US) and is incorporated herein by reference. However, HPC processing techniques have not been successfully adapted to the development of back contact structures for TFPV solar cells.

The back contact structure for TFPV solar cells must meet a number of requirements such as high conductivity, good ohmic contact to the absorber layer, good ohmic contact to the TCO layer for monolithic integration, good adhesion to the substrate, good adhesion to the tabs, ease of scribing, thermo-mechanically stable during manufacturing and during deployment in the field, low cost, high deposition rate, a coefficient of thermal expansion preferably similar to the substrate and other materials in the TFPV solar cell stack, high reflectance, electromigration resistance, etc. It is difficult to develop a single material that will meet all of these requirements.

Therefore, there is a need to develop back contact material stacks that address each of the requirements listed above to improve the efficiency of TFPV solar cells. In addition to meeting the required materials properties, the back contact material stacks must also meet the requirements of low cost and ease of manufacturing.

### SUMMARY OF THE INVENTION

In some embodiments of the present invention, material stacks are formed to address each of the requirements listed above. Adhesion-promoter and diffusion barrier layers are formed to ensure good adhesion to the substrate and to control the diffusion of components such as Na out of the substrate or to control the diffusion of components from the material stacks into the substrate. Inexpensive, high conductivity materials are used as primary bulk current transport layers. Stress management and diffusion barrier layers are used throughout the back contact material stack to control the stress within the material stack and to prevent the materials from the current transport layers from diffusing into the absorber and buffer layers formed above the back contact material stack. High reflectivity layers are used to improve the light absorption by the TFPV solar cell. Interface layers are used to ensure good ohmic contact between the back contact material stack and the absorber layer.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a schematic diagram for implementing combinatorial processing and evaluation.

FIG. 2 is a schematic diagram for illustrating various process sequences using combinatorial processing and evaluation.

FIG. 3 illustrates a schematic diagram of a simple CIGS or CZTS TFPV stack according to an embodiment described herein.

FIG. 4 illustrates a schematic diagram of a new TFPV back contact stack according to an embodiment described herein.

FIG. 5 illustrates a schematic diagram of a new TFPV back contact stack according to an embodiment described herein.

FIG. 6 illustrates a schematic diagram of a new TFPV back contact stack according to an embodiment described herein.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

A general class of PV absorber films of special interest is formed as multinary compounds from Groups IB-IIIA-VIA of the periodic table. Group IB includes Cu, Ag, and Au. Group IIA includes B, Al, Ga, In, and Tl. Group VIA includes O, S, Se, Te, and Po. Additionally, the IB-IIIA-VIA materials can be doped with dopants from Groups VIII, IIB, IVA, VA, and VIIA of the periodic table. Group VII includes Fe, Ru, Os, Co, Rh, Ir, Ni, Pd, and Pt. Group IIB includes Zn, Cd, and Hg. Group IVA includes C, Si, Ge, Sn, and Pb. Group VA includes N, P, As, Sb, and Bi. Group VIIA includes F, CI, Br, I, and At. Other potential absorber materials of interest include cuprous oxide, iron sulfide, etc. As used herein, “CIGS” will be understood to represent the entire range of related alloys denoted by Cu(InₓGa₁₋ₓ)(S_{y}Se_{2-y}) where 0≦x≦1 and 0≦y≦2. As used herein, “CZTS” will be understood to represent the entire range of related alloys denoted by Cu₂ZnSn(S_{y}Se_{1-y})₄ where 0≦y≦1.

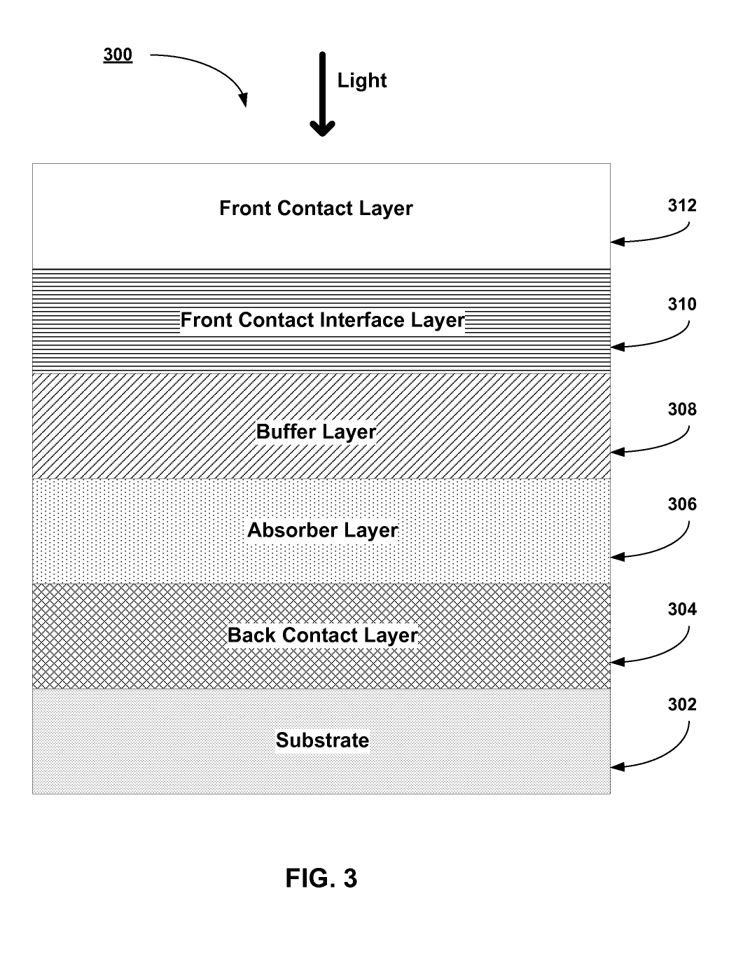

In FIGS. 3-6 below, a TFPV material stack is illustrated using a simple planar structure. Those skilled in the art will appreciate that the description and teachings to follow can be readily applied to any simple or complex TFPV solar cell structure. The drawings are for illustrative purposes only and do not limit the application of the present invention.

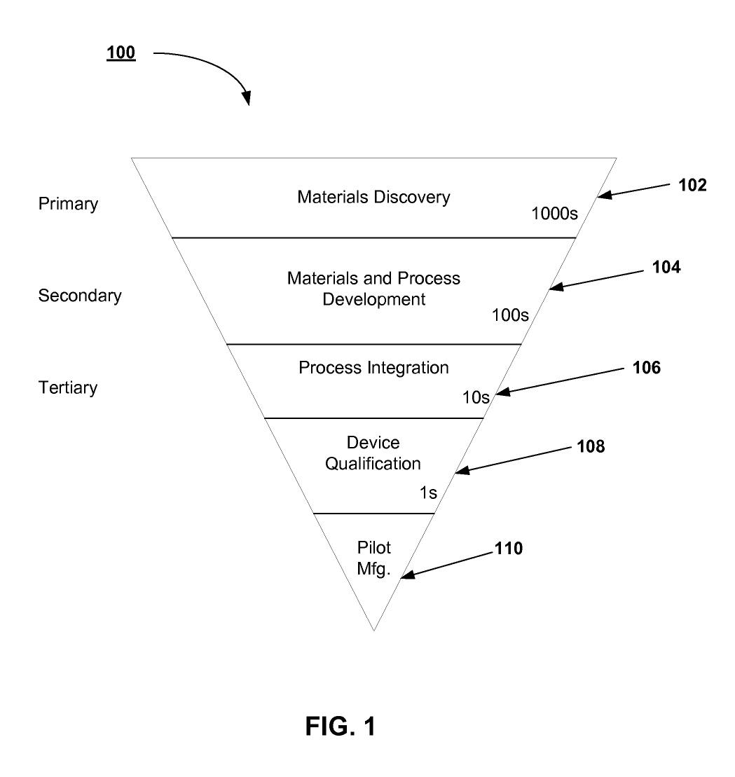

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of TFPV manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a TFPV device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a TFPV device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the TFPV device. For example, such structures may include, but would not be limited to, contact layers, buffer layers, absorber layers, or any other series of layers or unit processes that create an intermediate structure found on TFPV devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

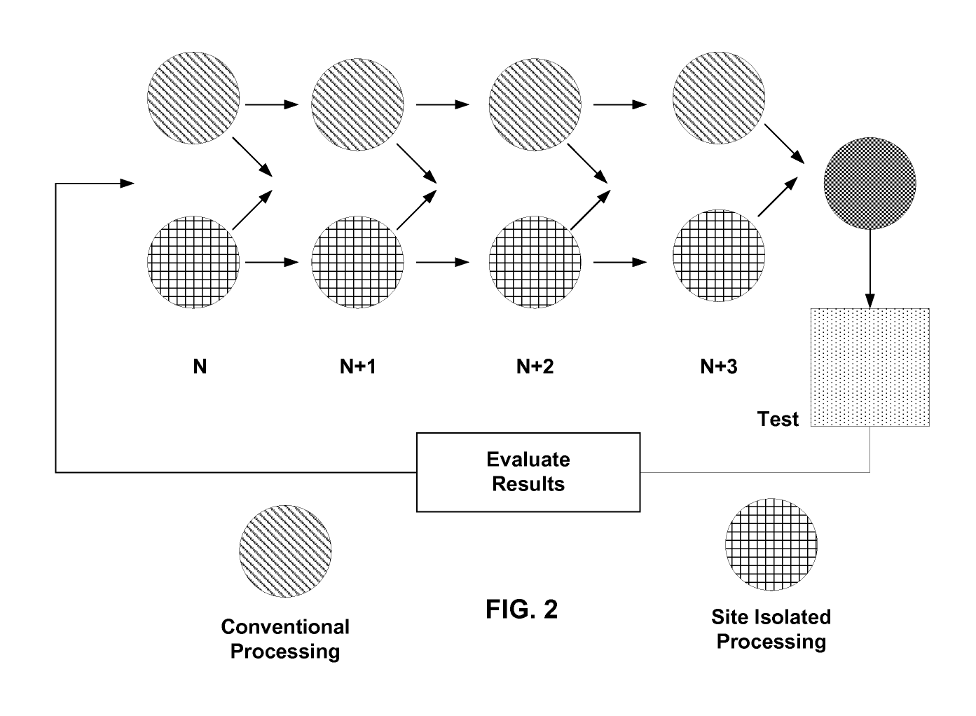

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in TFPV manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

FIG. 3 illustrates a schematic diagram of a simple TFPV solar cell stack consistent with some embodiments of the present invention. The convention will be used wherein light is assumed to be incident upon the top of the material stack as illustrated. This generic diagram would be typical of either a CIGS TFPV solar cell or a CZTS TFPV solar cell. The difference being the choice of materials for the absorber layer. A back contact layer, 304, is formed on a substrate, 302. TFPV devices may be fabricated on inexpensive substrates such as glass, plastics, and thin sheets of metal. Examples of suitable substrates comprise float glass, low-iron glass, borosilicate glass, flexible glass, specialty glass for high temperature processing, stainless steel, carbon steel, aluminum, copper, polyimide, plastics, etc. Typically, suitable substrates comprise soda lime glass (SLG). An example of a suitable back contact layer material is Mo. The back contact layer is typically formed using a physical vapor deposition (PVD—specifically sputtering) process but may also be formed using an evaporation process. The thickness of the back contact layer is typically between about 0.3 um and about 1.0 um.

A p-type absorber layer, 306, of CIGS or CZTS is then deposited on top of the back contact layer. The absorber layer may be formed using a variety of techniques such as PVD, co-evaporation, printing or spraying of inks, CVD, etc. Advantageously, the absorber layer is deficient in Cu. The Cu deficiency may be controlled by managing the deposition conditions. Advantageously, a small amount of Na is contained in the absorber layer. The Na may be added by out-diffusion from the SLG substrate or may be purposely added in the form of a sodium salt like NaF or Na₂Se, prior, during, or after the deposition of the precursor or final absorber layer. Optionally, the absorber layer undergoes a selenization process after formation to fill the Se vacancies within the matrix. The selenization process involves the exposure of the absorber layer to H₂Se, Se vapor, or diethylselenide (DESe) at temperatures between about 400 C and 600 C. During the selenization process, a layer of Mo(S)Se₂ (not shown) forms at the back contact/absorber layer interface and forms a good ohmic contact between the two layers. The thickness of the absorber layer is typically between about 1.0 um and about 3.0 um. The performance of the absorber layer is sensitive to materials properties such as crystallinity, grain size, surface roughness, composition, defect concentration, etc. as well as processing parameters such as temperature, deposition rate, thermal treatments, etc.

An n-type buffer layer, 308, is then deposited on top of the absorber layer or optional Mo(S)Se₂ layer if present. Examples of suitable n-type buffer layers comprise CdS, ZnS, CdZnS, In2S3, In2(S,Se)3, Zn(O,S), etc. CdS is the material most often used as the n-type buffer layer in CIGS or CZTS TFPV solar cells. The buffer layer may be deposited using chemical bath deposition (CBD), chemical surface deposition, ion-layer-gas-reaction (ILGAR), ALD, PVD (sputtering), ink deposition, spraying, electro-plating, or evaporation. The thickness of the buffer layer is typically between about 50 nm and about 80 nm, but can be as thin as 5-20 nm. The performance of the buffer layer is sensitive to materials properties such as crystallinity, grain size, surface roughness, composition, defect concentration, etc. as well as processing parameters such as temperature, deposition rate, thermal treatments, etc.

Optionally, an intrinsic ZnO (iZnO) layer, 310, is then formed on top of the buffer layer. The iZnO layer is a high resistivity material and forms part of the transparent conductive oxide (TCO) stack that serves as part of the front contact structure. The TCO stack is formed from transparent conductive metal oxide materials and collects charge across the face of the TFPV solar cell. The iZnO layer makes the TFPV solar cell less sensitive to lateral non-uniformities caused by differences in composition or defect concentration in the absorber and/or buffer layers. The iZnO layer is typically between about 30 nm and 80 nm in thickness. The iZnO layer is typically formed using a reactive PVD (sputtering) technique or CVD technique, but can be electro-plated, deposited by ink, or deposited by chemical surface deposition, chemical bath deposition, or other means. A low resistivity top TCO layer, 312, (examples include Al:ZnO (AZO), InSnO (ITO), InZnO, B:ZnO, Ga:ZnO, F:ZnO, F:SnO₂, etc.) is formed on top of the iZnO layer. The top TCO layer is typically between about 0.3 um and 2.0 um in thickness. The top TCO layer is typically formed using a reactive PVD (sputtering) technique or CVD technique, but other techniques, like electro-plating or ink deposition are used as well.

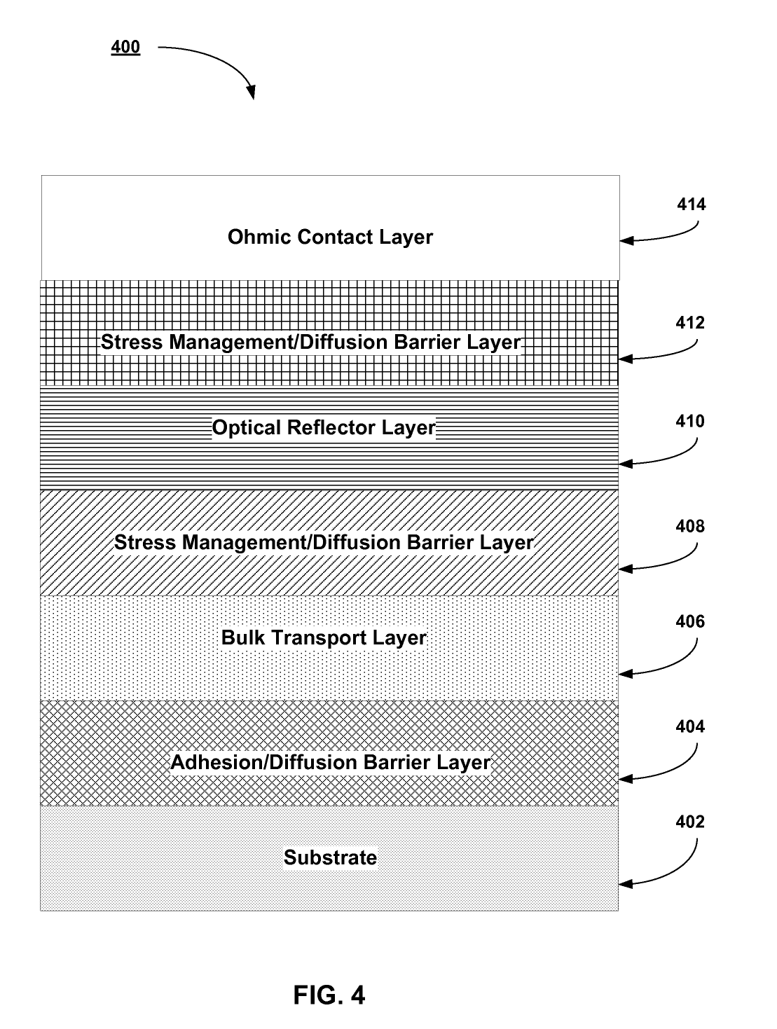

FIG. 4 illustrates a schematic diagram of a novel TFPV back contact material stack for a TFPV solar cell stack consistent with some embodiments of the present invention. An adhesion promoter and diffusion barrier layer, 404, is formed on substrate, 402. That is, layer, 404 serves a dual purpose as both an adhesion promoter layer and as a diffusion barrier layer. Typically, suitable substrates comprise SLG. Examples of materials suitable as an adhesion promoter and diffusion barrier layer comprise metal oxides and metal oxy-nitrides such as TiOₓ, CrOₓ, AlOₓ, SiOₓN_{y}, etc. This layer ensures that the back contact material stack and subsequent absorber, buffer, and front contact layers have good adhesion to the substrate. Additionally, this layer is used to control the diffusion of components such as Na out of the substrate and into the TFPV solar cell device. Metal oxides and metal oxy-nitrides are generally good adhesion promoters and diffusion barriers. The adhesion promoter and diffusion barrier layer is typically formed using a PVD (sputtering) technique but may also be formed using an evaporation technique, CVD technique, sol-gel coating technique, or deposition of polysilazanes. The thickness of the adhesion promoter and diffusion barrier layer is typically between about 10 nm and 100 nm. The development of this layer may be achieved using high productivity combinatorial techniques as discussed previously. In the case of a PVD deposition technique, parameters such as film composition, target composition, target to substrate distance, power, power type (i.e. AC or DC), pressure, sputtering gas, temperature, substrate bias, etc. may be varied in a combinatorial manner to determine their affect on the properties of the deposited film. In the case of a CVD deposition technique, parameters such as film composition, precursor gas composition, pressure, reactive gas composition, temperature, etc. may be varied in a combinatorial manner to determine their affect on the properties of the deposited film.

A bulk current transport layer, 406, is formed on the adhesion promoter and diffusion barrier layer, 404. The bulk current transport layer, 406, serves as the primary conductor to carry current generated by the solar cell to the contacts of the solar panel. Examples of materials suitable for the bulk current transport layer comprise high conductivity metals, metal alloys, conductive metal oxides, conductive metal nitrides, conductive metal silicides, and combinations thereof. Specific examples include Al, Cu, Mo, W, Ta, Nb, Cr, Ti, Ni, stainless steel, TCO materials, alloys based on Cu, Zn, and Ni (nickel silver), etc. In some embodiments of the present invention, the bulk current transport layer is a non-transparent or poorly-transparent conductive metal oxide. Because of the placement within the TFPV solar cell stack, the conductive metal oxide does not have to be highly transparent. Therefore, conductive metal oxide materials that have high conductivities, but may not be highly transparent can be used as the bulk current transport layer. The bulk current transport layer is typically formed using a PVD technique but may also be formed using an evaporation technique or a CVD technique. The thickness of the bulk current transport layer is typically between about 0.3 um and 2.0 um. The development of this layer may be achieved using high productivity combinatorial techniques as discussed previously. In the case of a PVD deposition technique, parameters such as film composition, target composition, target to substrate distance, power, power type (i.e. AC or DC), pressure, sputtering gas, temperature, substrate bias, etc. may be varied in a combinatorial manner to determine their affect on the properties of the deposited film. In the case of a CVD deposition technique, parameters such as film composition, precursor gas composition, pressure, reactive gas composition, temperature, etc. may be varied in a combinatorial manner to determine their affect on the properties of the deposited film.

An optional stress management/diffusion barrier layer, 408, may be formed on the bulk current transport layer, 406. One of the roles of the stress management/diffusion barrier layer is to relieve stresses that may have accumulated during the formation of the underlying layers or during subsequent processing (heat treatments). This improves the adhesion of the TFPV solar cell stack to the substrate, improving the performance and the reliability of the device. A second role of the stress management/diffusion barrier layer is to act as a diffusion barrier to prevent the unwanted diffusion of materials within the TFPV solar cell stack. This is especially important when highly reflective layers are incorporated to improve the light absorption by the TFPV solar cell as described below. Examples of materials suitable for the stress management/diffusion barrier layer comprise metal oxides, metal nitrides, metal silicides, and combinations thereof. Specific examples include SnO₂, TiN, TCO materials such as ZnO, CrOₓ, NiOₓ, Cr—Ni—O, etc. Examples of TCO materials comprise tin oxide doped with F, zinc oxide doped with one or more of Al, F, B, Or Ga, or indium oxide doped with Sn. A general discussion of TCO materials may be found in the book, “Handbook of Transparent Conductors” edited by Ginley et. al., published by Springer, with a copyright date of 2010 (Library of Congress Control Number 2010935196). The stress management/diffusion barrier layer is typically formed using a PVD technique but may also be formed using an evaporation technique or a CVD technique. The thickness of the stress management/diffusion barrier layer is typically between about 10 nm and 500 nm. The development of this layer may be achieved using high productivity combinatorial techniques as discussed previously. In the case of a PVD deposition technique, parameters such as film composition, target composition, target to substrate distance, power, power type (i.e. AC or DC), pressure, sputtering gas, temperature, substrate bias, etc. may be varied in a combinatorial manner to determine their affect on the properties of the deposited film. In the case of a CVD deposition technique, parameters such as film composition, precursor gas composition, pressure, reactive gas composition, temperature, etc. may be varied in a combinatorial manner to determine their affect on the properties of the deposited film.

An optical reflector layer, 410, is formed on the stress management/diffusion barrier layer, 408. The role of the optical reflector layer is to reflect light that has not been absorbed back through the absorber layer to improve the light absorption by the TFPV solar cell by increasing the path length of the light within the solar cell. Examples of materials suitable for the optical reflector layer comprise highly reflective metals, metal alloys, metal oxides, metal nitrides, metal silicides, and combinations thereof. Specific examples include Ag, Al, Cu, ZrN, TiN, alloys of Cu, Ni, and Zn (nickel silver), etc. The optical reflector layer is typically formed using a PVD technique but may also be formed using an evaporation technique or a CVD technique. The thickness of the stress management/diffusion barrier layer is typically between about 10 nm and 500 nm. The materials used for the optical reflector layer generally have high diffusivities through the materials used in TFPV solar cells. Therefore, this layer must be captured between two stress management/diffusion barrier layers. A first stress management/diffusion barrier layer was described previously as layer, 408. A second optional stress management/diffusion barrier layer, 412, may optionally be formed on the optical reflector layer, 410. This layer is required if an optical reflector layer is incorporated into the back contact material stack. One of the roles of the second stress management/diffusion barrier layer is to relieve stresses that may have accumulated during the formation of the underlying layers. This improves the adhesion of the TFPV solar cell stack to the substrate, improving the performance and the reliability of the device. A second role of the second stress management/diffusion barrier layer is to act as a diffusion barrier to prevent the unwanted diffusion of materials within the TFPV solar cell stack. This is especially important when highly reflective layers are incorporated to improve the light absorption by the TFPV solar cell as described previously. Examples of materials suitable for the stress management/diffusion barrier layer comprise metal oxides, metal nitrides, metal silicides, and combinations thereof. Specific examples include SnO₂, TiN, ZnO, TCO materials, etc. The second stress management/diffusion barrier layer is typically formed using a PVD technique but may also be formed using an evaporation technique or a CVD technique. The thickness of the second stress management/diffusion barrier layer is typically between about 10 nm and 500 nm. The development of this layer may be achieved using high productivity combinatorial techniques as discussed previously. In the case of a PVD deposition technique, parameters such as film composition, target composition, target to substrate distance, power, power type (i.e. AC or DC), pressure, sputtering gas, temperature, substrate bias, etc. may be varied in a combinatorial manner to determine their affect on the properties of the deposited film. In the case of a CVD deposition technique, parameters such as film composition, precursor gas composition, pressure, reactive gas composition, temperature, etc. may be varied in a combinatorial manner to determine their affect on the properties of the deposited film.

A MoS₂ or MoSe₂, (herein labeled Mo(S)Se₂) layer, 414, is formed on the second stress management/diffusion barrier layer, 412. The Mo(S)Se₂ layer forms a good ohmic contact between the back contact material stack and the absorber layer to be formed subsequently. The Mo layer is typically formed using a PVD technique but may also be formed using an evaporation technique or a CVD technique. The Mo layer reacts with Se in the material stack to form Mo(S)Se₂. The thickness of the Mo(S)Se₂ layer is typically between about 10 nm and 100 nm.

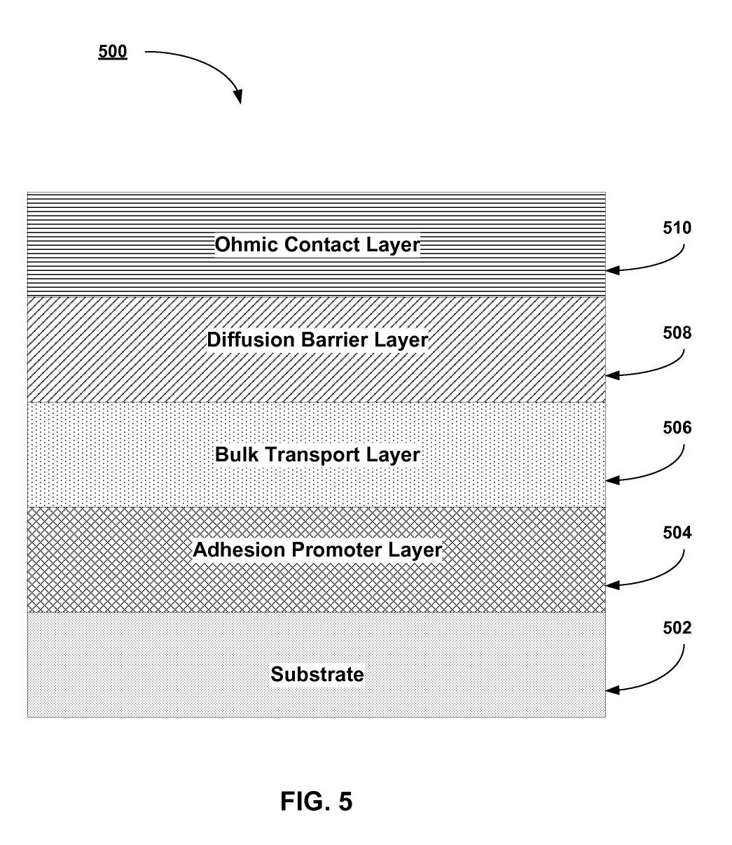

FIG. 5 illustrates a schematic diagram of a novel TFPV back contact material stack according to an embodiment described herein. Cu is a high conductivity metal that has been successfully implemented as an interconnect material in semiconductor devices. The performance of TFPV solar cells would be improved if Cu could be used as the bulk current transport layer. Cu has a higher conductivity than Mo and is also less expensive. However, Cu readily diffuses into the CIGS or CZTS absorber layers and potentially fills the Cu vacancies that are responsible for the p-type doping in CIGS and CZTS absorber materials. The filling of these vacancies would degrade the open circuit voltage performance of the solar cell. Therefore, Cu cannot be effectively used as a standalone material in a CIGS or CZTS TFPV solar cell. In FIG. 5, an adhesion promoter and diffusion barrier layer, 504, is formed on a substrate, 502. Typically, suitable substrates comprise SLG. Examples of materials suitable as an adhesion promoter and diffusion barrier layer comprise refractory metals or metal nitrides such as Ti, TiN, Ta, TaN, etc. This layer ensures that the back contact material stack and subsequent absorber, buffer, and front contact layers have good adhesion to the substrate. Additionally, this layer is used to control the diffusion of components such as Na out of the substrate and into the TFPV solar cell device. The adhesion promoter and diffusion barrier layer is typically formed using a PVD technique but may also be formed using an evaporation technique or a CVD technique. The thickness of the adhesion promoter and diffusion barrier layer is typically between about 10 nm and 100 nm. The development of this layer may be achieved using high productivity combinatorial techniques as discussed previously. In the case of a PVD deposition technique, parameters such as film composition, target composition, target to substrate distance, power, power type (i.e. AC or DC), pressure, sputtering gas, temperature, substrate bias, etc. may be varied in a combinatorial manner to determine their affect on the properties of the deposited film. In the case of a CVD deposition technique, parameters such as film composition, precursor gas composition, pressure, reactive gas composition, temperature, etc. may be varied in a combinatorial manner to determine their affect on the properties of the deposited film.

A bulk current transport layer, 506, is formed on the adhesion promoter and diffusion barrier layer, 504. Examples of materials suitable for the bulk current transport layer comprise high conductivity metals, metal alloys, conductive metal oxides, conductive metal nitrides, conductive metal silicides, and combinations thereof. Specific examples include Al, Cu, Mo, W, Ta, Nb, Cr, Ti, Ni, stainless steel, alloys based on Cu, Zn, and Ni (nickel silver), etc. The bulk current transport layer is typically formed using a PVD technique but may also be formed using an evaporation technique or a CVD technique. The thickness of the bulk current transport barrier layer is typically between about 0.3 um and 2.0 um. The development of this layer may be achieved using high productivity combinatorial techniques as discussed previously. In the case of a PVD deposition technique, parameters such as film composition, target composition, target to substrate distance, power, power type (i.e. AC or DC), pressure, sputtering gas, temperature, substrate bias, etc. may be varied in a combinatorial manner to determine their affect on the properties of the deposited film. In the case of a CVD deposition technique, parameters such as film composition, precursor gas composition, pressure, reactive gas composition, temperature, etc. may be varied in a combinatorial manner to determine their affect on the properties of the deposited film.

A diffusion barrier layer, 508, is formed on the bulk current transport layer, 506. Examples of materials suitable for the diffusion barrier layer comprise high conductivity metals, metal alloys, conductive metal oxides, conductive metal nitrides, conductive metal silicides, conductive metal carbides, conductive metal borides, or combinations thereof. Specific examples include Ta, TaN, WN, TaSi, TaC, TaSiN, WSiN, MoSiN, WBN, TiZrN, BaZrN₂, TiN, or combinations thereof etc. The diffusion barrier layer is typically formed using a PVD technique but may also be formed using an evaporation technique or a CVD technique. The thickness of the diffusion barrier layer is typically between about 10 nm and 100 nm. The development of this layer may be achieved using high productivity combinatorial techniques as discussed previously. In the case of a PVD deposition technique, parameters such as film composition, target composition, target to substrate distance, power, power type (i.e. AC or DC), pressure, sputtering gas, temperature, substrate bias, etc. may be varied in a combinatorial manner to determine their affect on the properties of the deposited film. In the case of a CVD deposition technique, parameters such as film composition, precursor gas composition, pressure, reactive gas composition, temperature, etc. may be varied in a combinatorial manner to determine their affect on the properties of the deposited film.

An ohmic contact layer, 510, is formed on the diffusion barrier layer, 508. Examples of materials suitable for the ohmic contact layer comprise high conductivity metals, metal alloys, and conductive metal oxides, or combinations thereof. Typically, the ohmic contact layer is Mo or Mo(S)Se₂. The ohmic contact layer is typically formed using a PVD technique but may also be formed using an evaporation technique or a CVD technique. The thickness of the ohmic contact layer is typically between about 10 nm and 100 nm. The remaining part of the TFPV solar cell would then be manufactured on top of this back contact stack.

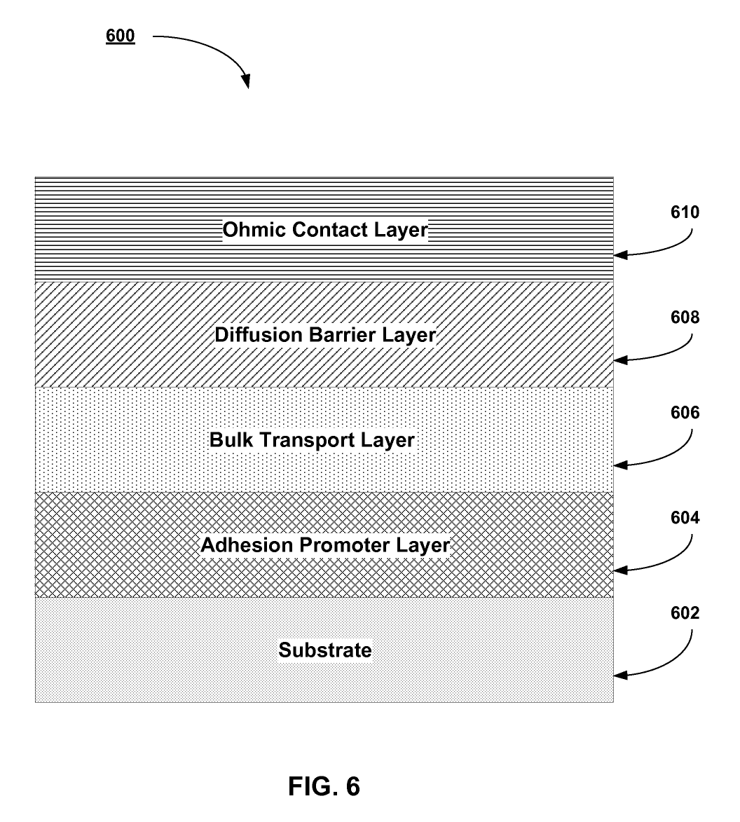

FIG. 6 illustrates a schematic diagram of a novel TFPV back contact material stack according to an embodiment described herein. Cu is a high conductivity metal that has been successfully implemented as an interconnect material in semiconductor devices. The performance of TFPV solar cells would be improved if Cu could be used as the bulk current transport layer. Cu has a higher conductivity than Mo and is also less expensive. However, Cu readily diffuses into the CIGS or CZTS absorber layers and fills the Cu vacancies that are responsible for the p-type doping in CIGS and CZTS absorber materials. The filling of these vacancies would degrade the open circuit voltage performance of the solar cell. Therefore, Cu cannot be used as a standalone material in a CIGS or CZTS TFPV solar cell. In FIG. 6, an adhesion promoter and diffusion barrier layer, 604, is formed on a substrate, 602. Typically, suitable substrates comprise SLG. Examples of materials suitable as an adhesion promoter and diffusion barrier layer comprise refractory metals or metal nitrides such as Ti, TiN, Ta, TaN, etc. This layer ensures that the back contact material stack and subsequent absorber, buffer, and front contact layers have good adhesion to the substrate. Additionally, this layer is used to control the diffusion of components such as Na out of the substrate and into the TFPV solar cell device. The adhesion promoter and diffusion barrier layer is typically formed using a PVD technique but may also be formed using an evaporation technique or a CVD technique. The thickness of the adhesion promoter layer is typically between about 10 nm and 100 nm. The development of this layer may be achieved using high productivity combinatorial techniques as discussed previously. In the case of a PVD deposition technique, parameters such as film composition, target composition, target to substrate distance, power, power type (i.e. AC or DC), pressure, sputtering gas, temperature, substrate bias, etc. may be varied in a combinatorial manner to determine their affect on the properties of the deposited film. In the case of a CVD deposition technique, parameters such as film composition, precursor gas composition, pressure, reactive gas composition, temperature, etc. may be varied in a combinatorial manner to determine their affect on the properties of the deposited film.

A bulk current transport layer, 606, is formed on the adhesion promoter and diffusion barrier layer, 604. Examples of materials suitable for the bulk current transport layer comprise high conductivity metals, metal alloys, conductive metal oxides, conductive metal nitrides, conductive metal silicides, and combinations thereof. Specific examples include Al, Cu, Mo, W, Ta, Nb, Cr, Ti, Ni, stainless steel, alloys based on Cu, Zn, and Ni (nickel silver), etc. The bulk current transport layer is typically formed using a PVD technique but may also be formed using an evaporation technique or a CVD technique. The thickness of the bulk current transport barrier layer is typically between about 0.3 um and 2.0 um. The development of this layer may be achieved using high productivity combinatorial techniques as discussed previously. In the case of a PVD deposition technique, parameters such as film composition, target composition, target to substrate distance, power, power type (i.e. AC or DC), pressure, sputtering gas, temperature, substrate bias, etc. may be varied in a combinatorial manner to determine their affect on the properties of the deposited film. In the case of a CVD deposition technique, parameters such as film composition, precursor gas composition, pressure, reactive gas composition, temperature, etc. may be varied in a combinatorial manner to determine their affect on the properties of the deposited film.

A diffusion barrier layer, 608, is formed on the bulk current transport layer, 606. Examples of materials suitable for the diffusion barrier layer comprise high conductivity metals, metal alloys, conductive metal oxides, conductive metal nitrides, conductive metal silicides, conductive metal carbides, conductive metal borides, or combinations thereof. Specific examples include Ta, TaN, WN, TaSi, TaC, TaSiN, WSiN, MoSiN, WBN, TiZrN, BaZrN₂, TiN, or combinations thereof etc. The diffusion barrier layer is typically formed using a PVD technique but may also be formed using an evaporation technique or a CVD technique. The thickness of the diffusion barrier layer is typically between about 10 nm and 100 nm. The development of this layer may be achieved using high productivity combinatorial techniques as discussed previously. In the case of a PVD deposition technique, parameters such as film composition, target composition, target to substrate distance, power, power type (i.e. AC or DC), pressure, sputtering gas, temperature, substrate bias, etc. may be varied in a combinatorial manner to determine their affect on the properties of the deposited film. In the case of a CVD deposition technique, parameters such as film composition, precursor gas composition, pressure, reactive gas composition, temperature, etc. may be varied in a combinatorial manner to determine their affect on the properties of the deposited film.

An ohmic contact layer, 610, is formed on the diffusion barrier layer, 608. Examples of materials suitable for the ohmic contact layer comprise high conductivity metals, metal alloys, and conductive metal oxides, or combinations thereof. One example of the ohmic contact layer is ZnSnO₃. ZnSnO₃ has a high work function (˜5.3 eV) and may form a good ohmic contact to the p-type CIGS or CZTS absorber layer. The ohmic contact layer is typically formed using a PVD technique but may also be formed using an evaporation technique or a CVD technique. The thickness of the ohmic contact layer is typically between about 10 nm and 100 nm. The development of this layer may be achieved using high productivity combinatorial techniques as discussed previously. In the case of a PVD deposition technique, parameters such as film composition, target composition, target to substrate distance, power, power type (i.e. AC or DC), pressure, sputtering gas, temperature, substrate bias, etc. may be varied in a combinatorial manner to determine their affect on the properties of the deposited film. In the case of a CVD deposition technique, parameters such as film composition, precursor gas composition, pressure, reactive gas composition, temperature, etc. may be varied in a combinatorial manner to determine their affect on the properties of the deposited film. The remaining part of the TFPV solar cell would then be manufactured on top of this back contact stack.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A thin film photovoltaic back contact material stack comprising:
a first layer,
a bulk current transport layer; and
an ohmic contact layer.

2. The thin film photovoltaic back contact material stack of claim 1 wherein the first layer comprises one of a metal, metal alloy, metal oxide, metal nitride, or a metal oxy-nitride.

3. The thin film photovoltaic back contact material stack of claim 2 wherein the first layer comprises one of Ta, TaN, WN, TaSi, TaSiN, WSiN, MoSiN, WBN, TiZrN, BaZrN₂, TiN, TiOₓ, CrOₓ, AlOₓ, or SiOₓN_{y}.

4. The thin film photovoltaic back contact material stack of claim 1 wherein the bulk current transport layer comprises one of a metal, metal alloy, conductive metal oxide, conductive metal nitride, conductive or metal silicide.

5. The thin film photovoltaic back contact material stack of claim 4 wherein the bulk current transport layer comprises one of Al, Cu, Mo, W, Ta, Nb, Cr, Ti, Ni, stainless steel, or transparent conductive oxide materials.

6. The thin film photovoltaic back contact material stack of claim 1 wherein the ohmic contact layer comprises one of Mo, MoS₂ or MoSe₂, ZnSnO₃.

7. The thin film photovoltaic back contact material stack of claim 1 further comprising an optical reflector layer positioned between the bulk current transport layer and the ohmic contact layer wherein the optical reflector layer is further positioned between two diffusion barrier layers.

8. The thin film photovoltaic back contact material stack of claim 7 wherein the optical reflector layer comprises one of a metal, metal alloy, metal oxide, metal nitride, or metal silicide.

9. The thin film photovoltaic back contact material stack of claim 8 wherein the optical reflector layer comprises one of Ag, Al, Cu, TiN, or transparent conductive oxide materials.

10. The thin film photovoltaic back contact material stack of claim 7 wherein the diffusion barrier layer comprises one of a metal oxide, metal nitride, metal oxy-nitride, or metal silicide.

11. The thin film photovoltaic back contact material stack of claim 8 wherein the diffusion barrier layer comprises one of TaN, WN, TaSi, TaSiN, WSiN, MoSiN, WBN, TiZrN, BaZrN₂, TiN, TiOₓ, CrOₓ, AlOₓ, SiOₓN_{y}, SnO₂, TiN, or transparent conductive oxide materials.

12. A thin film photovoltaic back contact material stack comprising:
a first layer,
a bulk current transport layer;
a diffusion barrier layer; and
an ohmic contact layer.

13. The thin film photovoltaic back contact material stack of claim 12 wherein the first layer comprises one of a metal. Metal alloy, metal oxide, metal nitride, or a metal oxy-nitride.

14. The thin film photovoltaic back contact material stack of claim 13 wherein the first layer comprises one of Ta, TaN, WN, TaSi, TaSiN, WSiN, MoSiN, WBN, TiZrN, BaZrN₂, TiN, TiOₓ, CrOₓ, AlOₓ, or SiOₓN_{y}.

15. The thin film photovoltaic back contact material stack of claim 12 wherein the bulk current transport layer comprises one of a metal, metal alloy, conductive metal oxide, conductive metal nitride, conductive or metal silicide.

16. The thin film photovoltaic back contact material stack of claim 15 wherein the bulk current transport layer comprises one of Al, Cu, Mo, W, Ta, Nb, Cr, Ti, Ni, stainless steel, or transparent conductive oxide materials.

17. The thin film photovoltaic back contact material stack of claim 12 wherein the diffusion barrier layer comprises one of a metal, metal alloy, conductive metal oxide, conductive metal nitride, or conductive metal silicide.

18. The thin film photovoltaic back contact material stack of claim 17 wherein the diffusion barrier layer comprises one of Ta, TaN, WN, TaSi, TaSiN, WSiN, MoSiN, WBN, TiZrN, BaZrN₂, or TiN.

19. The thin film photovoltaic back contact material stack of claim 12 wherein the ohmic contact layer comprises one of Mo, MoS₂, MoSe₂, or ZnSnO₃.
